(19) United States
(12) Patent Application Publication
(10) Pub. No.: US 2012/0100662 A1
(43) Pub. Date: Apr. 26, 2012

(54) METHOD OF MANUFACTURING SOLID-STATE IMAGE SENSOR

(75) Inventor: Kyouhei Watanabe, Yokohama-shi (JP)

(73) Assignee: CANON KABUSHIKI KAISHA, Tokyo (JP)

(21) Appl. No.: 13/275,889

(22) Filed: Oct. 18, 2011

(30) Foreign Application Priority Data
Oct. 25, 2010 (JP) 2010-238913
Oct. 12, 2011 (JP) 2011-225302

(51) Int. Cl. H01L 31/18

(52) U.S. Cl. 438/70; 257/E31.127

(57) ABSTRACT

A method of manufacturing a solid-state image sensor, includes forming a color-filter layer including a plurality of color filters on a wiring structure arranged on a semiconductor substrate on which a plurality of photoelectric converters are formed, forming a photosensitive microlens material layer on the color-filter layer, and forming microlenses by forming a latent image on the microlens material layer by exposing the microlens material layer using a photomask having a transmitted light distribution corresponding to a density of light-shielding portions each having a size smaller than a resolution limit of an exposure apparatus, and developing the microlens material layer, wherein the color-filter layer has a surface step, and the microlens material layer has a surface step corresponding to the surface step of the color-filter layer.

### BACKGROUND OF THE INVENTION

1. Field of the Invention

The present invention relates to a method of manufacturing a solid-state image sensor.

2. Description of the Related Art

A solid-state image sensor can be provided with a microlens for light collection for each pixel to improve the light collecting efficiency for a photoelectric converter (light-receiving unit). As a method of forming microlenses, there is widely known a method (to be referred to as a reflow method) of forming lenses by forming a photosensitive resin pattern in a columnar shape on a substrate, softening the photosensitive resin pattern by heating, and forming the resin surface into a spherical shape. Japanese Patent Laid-Open No. 5-183140 discloses a solid-state image sensor in which an anti-etching material layer for surface planarization and focal length adjustment is arranged on an array of three types of color-filter layers, and microlenses are arranged on the layer. This anti-etching material layer can be called a planarizing layer.

Solid-state image sensors have been developed toward a reduction in chip size and an increase in the number of pixels, and have been required to downsize the pixel. With downsizing of the pixel, however, an increase in the distance between each microlens and a corresponding photoelectric converter can lead to a deterioration in oblique incidence characteristics. When downsizing the pixel, therefore, it is important to decrease the distance between each microlens and a corresponding photoelectric converter. Using the structure disclosed in Japanese Patent Laid-Open No. 5-183140, however, makes it difficult to decrease the distance between each microlens and a corresponding photoelectric converter, because of the presence of a planarizing layer. Therefore, a structure including a planarizing layer is disadvantageous in terms of securing oblique incidence characteristics when promoting smaller pixels.

In some cases, in order to decrease the distance between each microlens and a corresponding photoelectric converter, microlenses are formed on color-filter layers so as to be in contact with them by the reflow method without forming any planarizing layer. In such a case, the surface steps of color filters can be reflected in the surface of a photosensitive resin which is applied onto the color filters to form microlenses. This can cause variations in positions on a photosensitive resin surface at the respective pixels relative to the image plane (best focus position) of an exposure apparatus and variations in the size of a columnar pattern formed through an exposure process and developing process for the photosensitive resin. This will cause variations in the shapes of microlenses.

### SUMMARY OF THE INVENTION

The present invention provides a technique advantageous in facilitating shape control of microlenses while decreasing the distance between each microlens and a corresponding photoelectric converter.

One of the features of the present invention provides a method of manufacturing a solid-state image sensor, comprising forming a color-filter layer including a plurality of color filters on a wiring structure arranged on a semiconductor substrate on which a plurality of photoelectric converters are formed, forming a photosensitive microlens material layer on the color-filter layer, and forming microlenses by forming a latent image on the microlens material layer by exposing the microlens material layer using a photomask having a transmitted light distribution corresponding to a density of light-shielding portions each having a size smaller than a resolution limit of an exposure apparatus, and developing the microlens material layer, wherein the color-filter layer has a surface step, and the microlens material layer has a surface step corresponding to the surface step of the color-filter layer.

Further features of the present invention will become apparent from the following description of exemplary embodiments with reference to the attached drawings.

### BRIEF DESCRIPTION OF THE DRAWINGS

FIGS. 1A to 1E are schematic sectional views showing a method of manufacturing a solid-state image sensor or microlenses in an embodiment of the present invention;

FIG. 2 is a graph exemplarily showing the amounts of change in inter-lens gap as the defocus amount of an exposure apparatus changes;

FIG. 3 is a view exemplarily showing the arrangement of a photomask; and

FIG. 4 is a view exemplarily showing the arrangement of the photomask.

### DESCRIPTION OF THE EMBODIMENTS

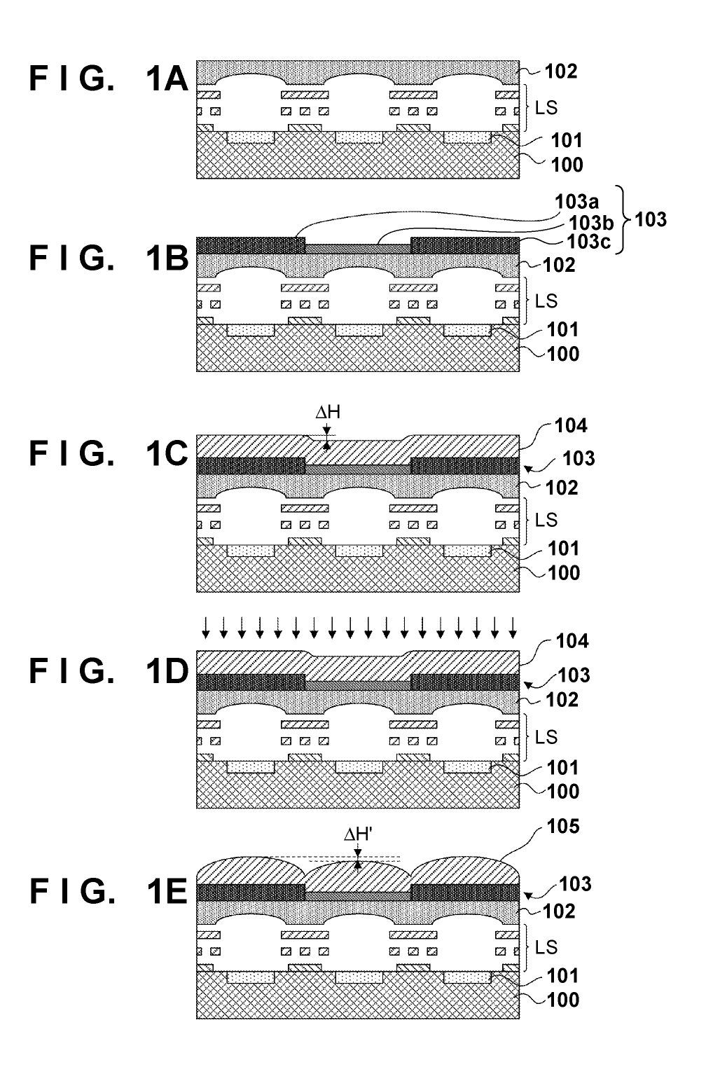

A method of manufacturing a solid-state image sensor or microlenses according to an embodiment of the present invention will be described with reference to FIGS. 1A to 1E. In this case, the solid-state image sensor can be, for example, a MOS sensor or a CCD sensor. The following will exemplify a case in which the solid-state image sensor is a MOS sensor. The step shown in FIG. 1A includes forming photoelectric converters (light-receiving units) 101 and MOS transistors on a semiconductor substrate 100, forming a wiring structure LS on the resultant structure, and forming a planarizing layer 102 on the wiring structure LS. The wiring structure LS can include a plurality of wiring layers and a plurality of interlayer insulation films which insulate the wiring layers. The wiring structure LS can also include inner microlenses on its upper surface. The planarizing layer 102 is preferably made of a material having high transmittance for light having wavelengths in the visible light range. For example, the planarizing layer 102 can be formed from a resin such as an acrylic resin or a polystyrene-based resin. The planarizing layer 102 can be formed by, for example, a spin coating method.

As shown in FIG. 1B, a color-filter layer 103 is formed on the planarizing layer 102. The color-filter layer 103 can be formed from an array of a plurality of color filters 103a, 103b, and 103c in FIG. 1B. The color-filter layer 103 can be formed by, for example, patterning a photosensitive resin colored with a dye or pigment by a photolithography method. The color-filter layer 103 can have surface steps (steps appearing on the surface). This is because the plurality of color filters constituting the color-filter layer 103 can be manufactured in a separate step. That is, the surface steps of the color-filter layer 103 can be formed by differences in surface height between the color filters of different colors.

As shown in FIG. 1C, a photosensitive microlens material layer 104 is formed on the color-filter layer 103. The microlens material layer 104 is preferably formed from a material having high transmittance for light having wavelengths in the visible light range. For example, a positive polystyrene-based resin is suitably used as such a material, and the above layer can be formed by the spin coating method. The microlens material layer 104 formed on the color-filter layer 103 can have surface steps corresponding to the surface steps of the color-filter layer 103. The magnitude of each surface step of the microlens material layer 104 can be evaluated as a difference ΔH between the surface of a portion having the maximum height and the surface of a portion having the minimum height as shown in FIG. 1C. The magnitude of each surface step of the microlens material layer 104 can be reduced by arranging a planarizing layer (to be referred to as an under-lens planarizing layer hereinafter) between the color-filter layer 103 and the microlens material layer 104. Forming an under-lens planarizing layer, however, will lead to an increase in the number of steps and a deterioration in oblique incidence characteristics. From the viewpoint of reducing the number of steps, it is preferable not to provide any under-lens planarizing layer. From the viewpoint of improving the incidence characteristics, it is preferable not to provide any under-lens planarizing layer or preferable to decrease its thickness. If no under-lens planarizing layer is provided, the microlens material layer 104 is formed in contact with the color-filter layer 103.

In the step shown in FIG. 1D, the exposure apparatus exposes the microlens material layer 104 to form a latent image corresponding to microlenses to be formed on the microlens material layer 104. The photomask has a transmitted light distribution corresponding to the density of dots (light-shielding portions) smaller than the resolution limit of the exposure apparatus (in this case, the size obtained by multiplying the minimum feature size on the substrate by the reciprocal of the projection magnification of the exposure apparatus). A method of forming such a transmitted light distribution can be called an area coverage modulation method. For example, Japanese Patent Laid-Open No. 2008-287212 discloses a method of forming microlenses using the area coverage modulation method. It is possible to manufacture a photomask in accordance with the technique disclosed in Japanese Patent Laid-Open No. 2008-287212. The microlens material layer 104 is exposed to a light intensity distribution based on the transmitted light distribution, and a latent image corresponding to the light intensity distribution is formed. In the step shown in FIG. 1E, microlenses 105 are formed by developing the microlens material layer 104 on which the latent image is formed. In this case, it is possible to smoothen the surfaces of the microlenses 105 by annealing, as needed, after the development.

Applying the area coverage modulation method can reduce manufacturing errors on the microlenses 105 due to the surface steps of the microlens material layer 104. That is, applying the area coverage modulation method can make the manufacturing errors on the microlenses 105 insensitive to the magnitudes of surface steps of the microlens material layer 104.

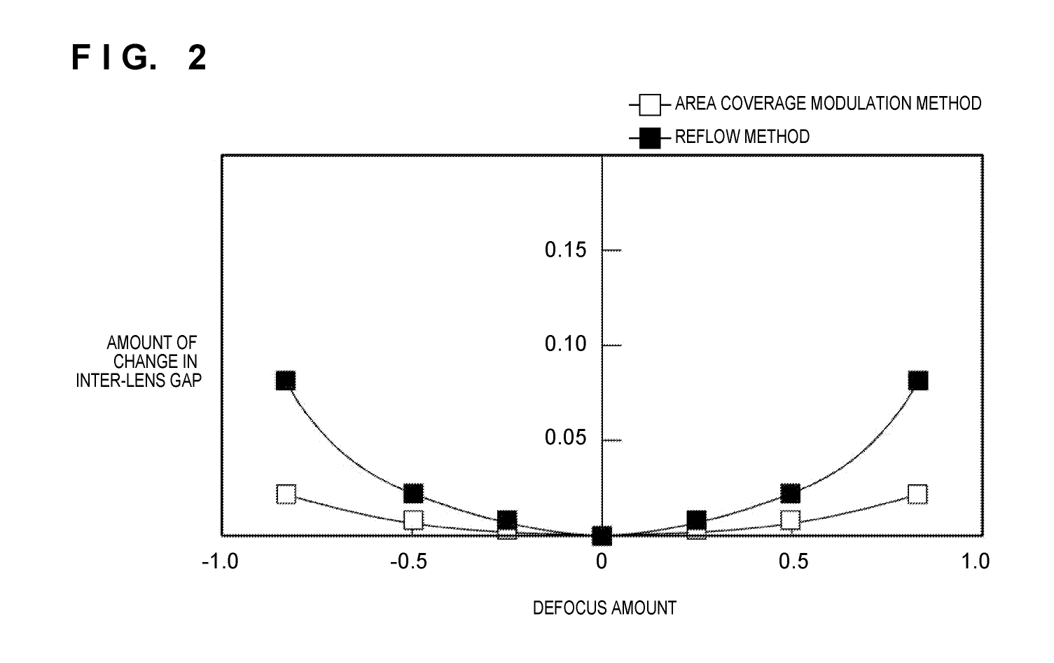

FIG. 2 is a graph exemplarily showing the amounts of change in inter-lens gap as the defocus amount of an exposure apparatus changes. In this graph, the abscissa represents the defocus amount of the exposure apparatus; and ordinate, the amounts of change in inter-lens gap. A defocus amount is the amount of shift between the surface of the microlens material layer 104 and the image plane of the projection optical system of the exposure apparatus. An inter-lens gap is the gap between adjacent microlenses of the formed microlens array. The amount of change in inter-lens gap is the amount of change relative to the inter-lens gap at an arbitrary defocus amount from the inter-lens gap at a defocus amount of 0. That the inter-lens gap is large indicates that the dimensional error of the corresponding microlens due to defocus is large. FIG. 2 exemplarily shows the amounts of change in inter-lens gap when microlenses are formed by the area coverage modulation method and the amounts of change in inter-lens gap when microlenses are formed by the reflow method. In this case, the reflow method is a method of forming a pattern having a rectangular section by exposing a microlens material layer using a photomask having a pattern with resolvable sizes and developing the resultant structure and forming its section into a curved surface by annealing (reflow).

It is obvious from FIG. 2 that the amounts of change in inter-lens gap on the microlens material layer 104 due to defocus in the area coverage modulation method are smaller than those in the reflow method. In this case, surface steps that are dependent on the surface steps of the color-filter layer 103 are formed on the microlens material layer 104. A Large surface step of the microlens material layer 104 indicates that the defocus amount is large. A large amount of change in inter-lens gap indicates that there are large manufacturing errors for a corresponding microlens (for example, dimensional errors and microlens heights). It is therefore obvious that the area coverage modulation method reduces the shape errors of the microlenses 105 due to the surface steps of the microlens material layer 104 more than the reflow method. This is because in the area coverage modulation method, each dot is not resolved. Letting ΔH′ be the height difference between the microlens, of the microlenses 105, which has the maximum height and the microlens which has the minimum height, since the area coverage modulation method reduces the height differences between the microlenses caused by surface steps, ΔH′<ΔH holds. For example, although not limiting the present invention, 0 μm<ΔH′<0.5 μm holds within the range of 0 μm<ΔH<0.5 μm. It can be said that the productivity of the microlenses 105 can be ensured while sufficient processing accuracy is maintained, within this range of height differences.

As described above, an exposure method using the area coverage modulation method can accurately control the shape (e.g., size) of each microlens even without forming any planarizing layer between the color-filter layer and the microlenses. Not forming any planarizing layer between a color-filter layer and microlenses is advantageous in decreasing the distance between each microlens and the color-filter layer. This contributes to an improvement in the oblique incidence characteristics of the solid-state image sensor including the microlenses. In addition to the above advantages, the area coverage modulation method has the advantage that it is possible to freely determine the transmitted light distribution of a photomask (that is, the light intensity distribution formed on a microlens material layer by the exposure apparatus) in accordance with the dot density of the photomask.

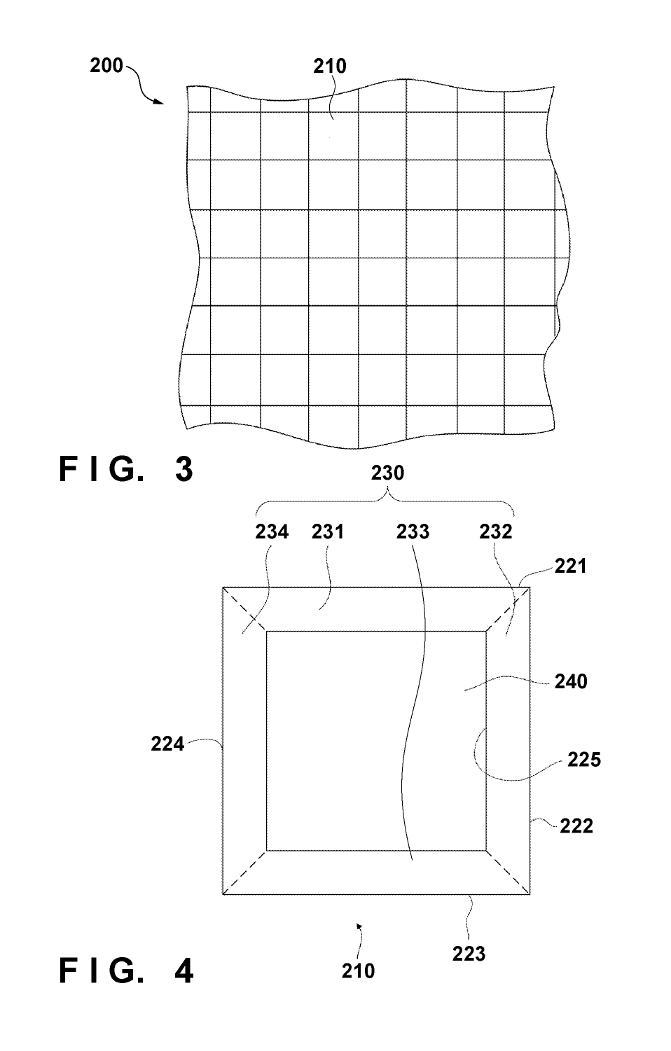

A photomask 200 suitable for the manufacture of the array of the microlenses 105 by photolithography method will be described next with reference to FIGS. 3 and 4. The photomask 200 has a microlens pattern constituted by light-shielding portions (dots) and non-light-shielding portions for the formation of microlenses, respectively, in a plurality of rectangular regions 210 arranged two-dimensionally. Each rectangular region is typically a square region. However, the shape of each region is not limited to this. Each light-shielding portion (dot) has a size which is not resolved by the wavelength (for example, 365 nm) of exposure light used in the photolithography method, and can typically have a rectangular or circular shape. Each rectangular region 210 includes a surrounding region 230 whose outer edge is defined by four sides 221 to 224 that define the boundary of the rectangular region 210, and a main region 240 whose boundary is defined by an inner edge 225 of the surrounding region 230. The surrounding region 230 is constituted by four strip regions 231 to 234 each having one of the four sides 221 to 224 as part of a contour line. For example, the strip region 231 has the side 221 as part of the contour line. A width W between each of the sides 221 to 224 as an outer edge of the surrounding region 230 and the inner edge 225 can be equal to or less than ½ the wavelength of exposure light used in the photolithography method. As exemplarily shown in FIG. 4, each of the strip regions 231 to 234 may have an elongated trapezoidal shape, a rectangular shape, or another shape.

Photomask data can be typically generated by a computer in accordance with a generation method according to a preferred embodiment of the present invention. The method for generating a photomask includes the first and second steps. In the first step, the computer determines the arrangement of light-shielding portions and non-light-shielding portions in the main region 240 of each rectangular region 210. This operation is equivalent to generating photomask data for each main region 240. In the first step, it is possible to tentatively determine the arrangement of light-shielding portions and non-light-shielding portions in each surrounding region 230 in addition to each main region 240. Note, however, that the arrangement of light-shielding portions and non-light-shielding portions in each surrounding region 230 is finally determined in the second step. In the second step, the computer can determine the arrangement of light-shielding portions and non-light-shielding portions in each surrounding region 230 such that the light-shielding portion densities become 0% or more and 15% or less, and the light-shielding portion densities in the strip regions 231 to 234 become equal to each other. This operation is equivalent to generating photomask data for each surrounding region 230. In this case, a light-shielding portion density (dot density) is defined as (area of light-shielding portions)/((area of light-shielding portions)+(area of non-light-shielding portions)). Photomask data includes a binary data string. Each light-shielding portion can be expressed by “1”, and each non-light-shielding portion can be expressed by “0”. Alternatively, each light-shielding portion can be expressed by “0”, and each non-light-shielding portion can be expressed by “1”.

If the width W of the surrounding region 230 exceeds ½ the wavelength of exposure light, a space is formed on a boundary portion between adjacent microlenses, and the light collecting efficiency can decrease. For this reason, the width W of the surrounding region 230 is preferably equal to or less than ½ the wavelength of exposure light. In addition, setting the light-shielding portion density of the surrounding region 230 to 0% or more and 15% or less can accelerate the photoreaction of a photosensitive lens material in the boundary portion between microlenses (or the peripheral portion of a corresponding microlens). This can make the shape of each microlens on a boundary portion similar to a target shape and improve light collecting efficiency. In addition, making the four strip regions 231 to 234 constituting the surrounding region 230 have the same light-shielding portion density can equalize the shapes of the respective microlenses.

In the above embodiment, it is possible to control a transmitted light distribution by changing the density of dots having the same size smaller than the resolution limit of the exposure apparatus. It is also possible to control a transmitted light distribution by the size of each dot smaller than the resolution limit of the exposure apparatus.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2010-238913, filed Oct. 25, 2010, and 2011-225302, filed Oct. 12, 2011 which are hereby incorporated by reference herein in their entirety.

What is claimed is:

1. A method of manufacturing a solid-state image sensor, comprising:
forming a color-filter layer including a plurality of color filters on a wiring structure arranged on a semiconductor substrate on which a plurality of photoelectric converters are formed;
forming a photosensitive microlens material layer on the color-filter layer; and
forming microlenses by forming a latent image on the microlens material layer by exposing the microlens material layer using a photomask having a transmitted light distribution corresponding to a density of light-shielding portions each having a size smaller than a resolution limit of an exposure apparatus, and developing the microlens material layer,
wherein the color-filter layer has a surface step, and the microlens material layer has a surface step corresponding to the surface step of the color-filter layer.

2. The method according to claim 1, wherein a surface step of the microlens satisfies 0 μm<ΔH 0.5 μm when the surface step of the microlens is evaluated as a difference ΔH between a height of a microlens having a maximum height and a height of a microlens having a minimum height.

3. The method according to claim 1, wherein the microlens material layer is formed in contact with the color-filter layer.

4. The method according to claim 1, wherein a surface step of the color-filter layer is formed by a height difference between color filters of different colors.

5. The method according to claim 1, wherein the photomask has a microlens pattern including light-shielding portions and non-light-shielding portions for forming the microlenses respectively in a plurality of rectangular regions arranged two-dimensionally, each of the rectangular regions includes a surrounding region whose outer edge is defined by four sides of said each rectangular region, and a main region whose boundary is defined by an inner edge of the surrounding region, the surrounding region includes four strip regions each having one of the four sides as part of a contour line, and a width between the outer edge and the inner edge of the surrounding region is not more than ½ a wavelength of exposure light, and
an arrangement of the light-shielding portions and the non-light-shielding portions in the surrounding region is determined such that a light-shielding portion density defined as (area of light-shielding portions)/((area of light-shielding portions)+(non-area of light-shielding portions)) becomes not less than 0% and not more than 15%, and the light-shielding portion densities of the four strip regions become equal to each other.
